(19) United States
(12) Patent Application Publication
(10) Pub. No.: US 2024/0419873 A1
(43) Pub. Date: Dec. 19, 2024

(54) EARLY DETECTION METHOD FOR NETWORK UNRELIABLE INFORMATION BASED ON ENSEMBLE LEARNING

(71) Applicant: HUBEI UNIVERSITY, Wuhan City (CN)

(72) Inventors: Dunhui YU, Wuhan City (CN); Yan ZHANG, Wuhan City (CN); Hao CHEN, Wuhan City (CN); Wanshan ZHANG, Wuhan City (CN); Wenwei LIU, Wuhan City (CN)

(73) Assignee: HUBEI UNIVERSITY, Wuhan City, HB (CN)

(21) Appl. No.: 18/739,362

(22) Filed: Jun. 11, 2024

(30) Foreign Application Priority Data
Jun. 15, 2023 (CN) 2023107083108

(51) Int. Cl. G06F 30/27

(52) U.S. Cl. CPC G06F 30/27

(57) ABSTRACT

The invention pertains to an early detection method for network unreliable information using ensemble learning, within the field of early detection technology for unreliable network data. It involves the following steps: (1) converting input text sequences into word vector sequences; (2) inputting these word vectors into three base models—Transformer, Bi-SATT-CAPS, and BiTCN—for classifying unreliable information; (3) training and predicting with these models to generate new training and test data sets; (4) weighting and merging these new data sets to create a new training set for the meta-learner SVM; (5) training the new set with the meta-learner SVM to obtain the final classification result. This method retains the text's grammatical and structural features, using only blog posts and early comments to accurately detect unreliable information. By employing an improved weight fusion strategy, the method leverages the strengths of the three base models to enhance early detection effectiveness.

### TECHNICAL FIELD

The invention relates to the field of early detection of network unreliable information, in particular to an early detection method for network unreliable information based on ensemble learning.

### BACKGROUND ART

Unreliable information detection is regarded as a binary classification problem in most studies, that is, the content to be detected is divided into two categories: unreliable information and reliable information. Among them, whether it is a detection method based on traditional machine learning or deep learning, the core is to extract features that are helpful for detection from the blog post itself and its related attributes, which is used for training and prediction, so as to judge whether the blog post to be detected is unreliable information or reliable information. These unreliable information detection methods mainly rely on selecting one or more of the text content features, social context features, and propagation structure features.

The defects of the above unreliable information detection methods are mainly reflected in the following two aspects:

(1) Grammatical and structural features are seriously loss when extracting content features:
the forms of unreliable information are complex and diverse, at the same time, the makers of unreliable information will also take various means to blur their intentions, so as to avoid the detection. The existing unreliable information detection methods have the problem of serious loss of grammatical and structural feature extraction when extracting content features, so that the detection effect of unreliable information is poor.

(2) There is still much room for improvement in the early detection ability of unreliable information:
most of the existing unreliable information detection methods are based on the fact that the blog post to be detected already has a large amount of feature information, social context features such as a large number of forwarding comments and propagation structure features. However, these features can be obvious enough when unreliable information is released for a long time, at which time unreliable information may have caused serious negative effects. These methods cannot have high accuracy before unreliable information has not been widely forwarded, commented and disseminated in the early stage of unreliable information release, and the early detection ability of unreliable information needs to be improved.

Therefore, it is necessary to propose an early detection method for network unreliable information, it is only necessary to select the text content features and a small number of forwarding comment features in the social context features to improve the detection effect of unreliable information, so as to achieve the effect of early detection of network unreliable information.

### SUMMARY OF THE INVENTION

The purpose of this invention is to provide an early detection method for network unreliable information based on ensemble learning, which can alleviate a problem of serious loss of grammatical and structural feature extraction in existing unreliable information detection methods, and it can preserve features captured in a data text of network unreliable information to the greatest extent, so as to improve a effect of network unreliable information detection. At the same time, it solves the problem that existing unreliable information detection methods cannot conduct accurate detection in an early stage due to a dependence on propagation structure features and social context features.

In order to achieve an above purpose, the invention provides a following technical scheme:

An early detection method for network unreliable information based on ensemble learning comprises following steps:
Step 1: converting an input text sequence into a word vector sequence: firstly integrating a corresponding forwarding comment c in an original blog post s to obtain a text sequence M=[m₁, m₂, . . . , mₙ] with a length of n, then using a pre-trained Glove to convert the text sequence M into a word vector sequence x, x=x₁, x₂, . . . , xₙ (xᵢ∈R_{d}), wherein d represents dimension;
Step 2: inputting the word vector sequence into three base models Transformer, Bi-SATT-CAPS, and BiTCN to complete a classification of unreliable information detection, using the base model Bi-SATT-CAPS to obtain classification method steps of unreliable information detection:
(1) inputting the word vector sequence x into a bidirectional LSTM for feature extraction, obtaining the vector by splicing hidden state vectors of a forward LSTM and a reverse LSTM to represent extracted features:

$${h}_{n} = [ \overline{{h}_{n}} , \overline{{h}_{n}} ]$$

wherein h̅ₙ̅ represents the hidden state vector of the forward LSTM, h̅ₙ̅ represents the hidden state vector of the reverse LSTM, [,] represents the splicing operation;
(2) using a multi-head self-attention mechanism to perform a multi-head self-attention calculation on an output hₙ of the bidirectional LSTM, achieving common attention to input information at different positions;
(2.1) W_{Q}, Wₖ, Wᵥ are different weight matrices, multiplying these weight matrices with hₙ to obtain Q, K, V matrices;
(2.2) splitting the obtained Q, K, V matrices according to a number of designed multi-head self-attention heads, and then calculating attention scores of three parts respectively;

$${h}_{i}^{head} = Attention ( {QW}_{i}^{Q} , {KW}_{i}^{K} , {VW}_{i}^{V} )$$

wherein hᵢ^{head} represents the output of an i-th head, Wᵢ^{Q}, Wᵢ^{K} and Wᵢ^{V} are the parameter matrices of Q, K and V in the i-th head respectively;
(2.3) merging calculation results:
wherein r is the number of heads of multi-head attention, W^{O} is the weight matrix when the multi-head self-attention mechanism merges the calculation results;
(2.4) obtaining an output feature v by merging and splicing final multi-head self-attention calculation results and passing them through a linear layer;
(3) inputting the output feature v of a previous step into an convolutional capsule layer;
(3.1) Between two adjacent capsules in the convolution capsule layer, multiplying a subcapsule vᵢ of an i-th layer by a weight matrix Wᵢ^{j} to obtain a prediction vector û_{j|i} from the subcapsule vᵢ to a parent capsule of a i+1-th layer:

$${\hat{u}}_{j \vert i} = {W}_{ij} {v}_{i}$$

(3.2) Calculating a coupling coefficient cᵢⱼ determined by a dynamic routing algorithm, setting an initial value of a logarithmic probability bᵢⱼ to 0, and through continuous transformation of cᵢⱼ, conducting an iterative update by using a softmax function:

$${c}_{ij} = \frac{exp ( {b}_{ij} )}{{\sum }_{j} exp ( {b}_{ij} )}$$

(3.3) Obtaining a final feature representation sⱼ of each parent capsule by a weight sum of all prediction vectors û_{j|i} from child capsules.

$${s}_{j} = {\sum }_{j} {c}_{ij} {\hat{u}}_{j \vert i}$$

(3.4) the parent capsule sⱼ conducts scaling by using an activation function Squash, and then obtaining a final parent capsule Vⱼ:

$${V}_{j} = \frac{{‖ {s}_{j} ‖}^{2}}{1 + {‖ {s}_{j} ‖}^{2}} \cdot \frac{{s}_{j}}{‖ {s}_{j} ‖}$$

(3.5) inputting the output vector Vⱼ of the convolutional capsule layer into the classification capsule for classification:

$${V}_{f} = f ( W \cdot {V}_{j} + B )$$

wherein W represents the weight matrix of the classification capsule, and B represents a bias term of the classification capsule;
(3.6) inputting a vector V_{f} obtained after the classification of a classification capsule into a softmax classifier for normalization, then completing detection and classification of unreliable information;
(3.7) wherein selecting a cross entropy function as a training loss function of the model, minimizing the cross entropy between a training predicted value and an actual value is goal:

$$L = \frac{1}{n} {\sum }_{x} [ y ln \hat{y} + ( 1 - y ) ln ( 1 - \hat{y} ) ]$$

wherein y and ŷ are the actual value and predicted value of a sample x respectively, n is the number of training samples, and L is a loss value;
Step 3: conducting training and prediction on the three base models according to a 5-fold cross-validation step, and obtaining three sets of new training data and test data, splicing the three sets of new test data as a new test set;
Step 4: giving each of the three base models a credibility, that is, a weight, weighting the three sets of new training data and merging them as a new training set to input into a meta-learner SVM, specific steps are:
(1) calculating an error rate of a t-th base model:

$${ϵ}_{t} = P ( {f}_{t} ( {\hat{y}}_{i} \neq {y}_{i} ) )$$

(2) calculating a weight αₜ according to the error rate:

$${α}_{t} = \frac{1 - {ϵ}_{i}}{{ϵ}_{i}}$$

(3) obtaining a final weight wₜ by normalizing the weight αₜ:

$${w}_{t} = \frac{{α}_{i}}{{{\sum }^{3}}_{i = 1} {α}_{i}}$$

(4) weighting three sets of new training data and merging them as the new training set to input into the meta-learner SVM;
Step 5: training the new training set by the meta-learner SVM, and obtaining the final classification result:

$$f ( x ) = sign ( w \cdot x + b )$$

wherein w is the weight matrix of the meta-learner SVM, and b is the bias term of the meta-learner SVM.

Preferably, in S2, the method of inputting the word vector sequence x into the base model Transformer is:

$$y = softmax ( {W}_{Trans} \cdot Transformer\_Encoder ( x ) )$$

wherein Transformer_Encoder (x) represents the output of the word vector sequence x of the input text after applying a Transformer encoder; W_{Trans} represents the weight matrix of output layer in the base model Transformer; the softmax ( ) function converts the model output into a probability distribution to select a category of unreliable information;
the method of inputting the word vector sequence x into the base model BiTCN model is:

$$y = softmax ( {W}_{BiTCH} * BiTCN ( x ) )$$

wherein BiTCN (x) represents the output obtained by applying BiTCN to the word vector sequence x of the input text; W_{BiTCH} represents the weight matrix of output layer in the base model BiTCN; the softmax ( ) function converts the model output into a probability distribution to select the category of unreliable information.

Preferably, the specific method of step 3 is:
(1) firstly, dividing the data of training set into five parts, conducting training by using four parts of the data of training set as the training set each time, and performing prediction by using a part of data of remaining training set as the test set;
(2) after completing the model training, predicting the data of test set to obtain prediction results;
(3) after repeating 5 times, that is, training the model for 5 times, splicing the 5 prediction results obtained on the training set to obtain the new set of features and training data, and arithmetically averaging the 5 prediction results on the test set to obtain a new set of test data;
(4) training the three base models through the above steps to obtain three sets of new training data and test data, splicing the three sets of new test data as the new test set.

The invention adopts the early detection method for network unreliable information based on ensemble learning, which has following beneficial effects:

(1) It can fully retain grammatical and structural features of the text, so as to improve the effect of network unreliable information detection:
the Bi-ATT-CAPS model proposed by the invention introduces the capsule network into the unreliable information detection task, the capsule network contains rich information such as position and direction of words, and there is a strong correlation between adjacent nodes, which retains underlying details in original data. These features are very consistent with a context relation and an order of the blog post and the data of forwarding comments on a network platform. It can well extract multi-grammatical features, semantic features and structural features, and preserve the features captured in the network unreliable information data text to the greatest extent, so as to improve the effect of network unreliable information detection.

(2) It can detect unreliable information with high accuracy by only using blog post and a small number of early forwarding comments, so as to realize a demand of early detection of network unreliable information:
the invention proposes an early detection method for network unreliable information based on ensemble learning combining with blog post content and a small number of forwarding comments in the early stage, the method does not depend on propagation structure characteristics and other social context features, it can achieve better results, and can have higher accuracy when the number of forwarding comments in the early stage of unreliable information release is small, so as to meet the needs of early detection of unreliable information in practical work.

(3) By using an improved weight Stacking fusion strategy, the advantages of the three base models are integrated to improve the early detection effect:
in the classical Stacking fusion strategy, the performance differences of different base models in the task are not distinguished, the prediction results of the three base models are regarded as equally important and they are input to the meta-learner. In the unreliable information detection task, the three base models have different detection accuracy for blog posts with different lengths. The invention uses the characteristics of that the three base models have different detection effects on blog posts with different lengths, which assigns the credibility to the base model, that is, a weight, then the weight new training set is input into the meta-learner for training, and the final classification result is obtained.

### BRIEF DESCRIPTION OF DRAWINGS

FIG. 1 is the flow chart of the early detection method for network unreliable information based on ensemble learning.

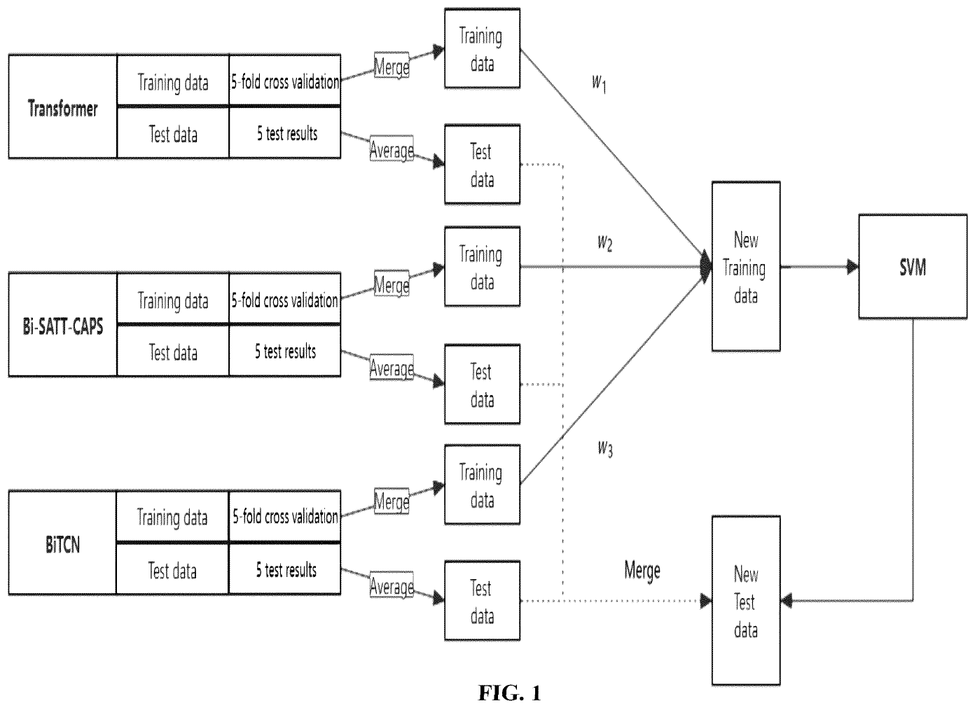

FIG. 2 is the overall structure diagram of the Bi-SATT-CAPS model in the early detection method for network unreliable information based on ensemble learning.

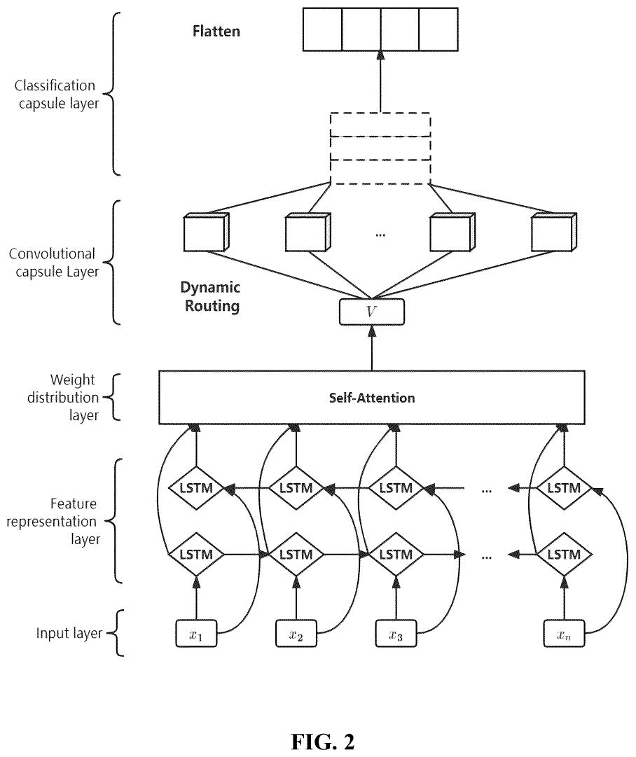

FIG. 3 is the result diagram of ablation experiment;

FIG. 4 is the result diagram of the early detection experiment.

### DETAILED DESCRIPTION OF THE EMBODIMENTS

The following is a further explanation of the technical scheme of the invention in combination with the attached drawings and embodiments.

An early detection method for network unreliable information based on ensemble learning, as shown in the figures, comprises the following steps:
Step 1: converting the input text sequence into a word vector sequence: first, integrating the corresponding forwarding comment c in the original blog post s to obtain a text sequence M=[m₁, m₂, . . . , mₙ] with a length of n, then using the pre-trained Glove to convert the text sequence M into a word vector sequence x, x=x₁, x₂, . . . , xₙ (xᵢ∈R_{d}), wherein d represents the dimension;
Step 2: inputting the word vector sequence into the three base models Transformer, Bi-SATT-CAPS, and BiTCN to complete the classification of unreliable information detection:
using the base model Bi-SATT-CAPS to obtain classification method steps of unreliable information detection:
(1) inputting the word vector sequence x into the bidirectional LSTM for feature extraction, obtaining the vector by splicing the hidden state vectors of the forward LSTM and the reverse LSTM to represent the extracted features:

$${h}_{n} = [ \vec{{h}_{n}} , \overleftarrow{{h}_{n}} ]$$

wherein h̅ₙ̅ represents the hidden state vector of the forward LSTM, h̅ₙ̅ represents the hidden state vector of the reverse LSTM, [,] represents the splicing operation;
(2) using the multi-head self-attention mechanism to perform the multi-head self-attention calculation on the output hₙ of the bidirectional LSTM, achieving common attention to the input information at different positions;
(2.1) W_{Q}, Wₖ, Wᵥ are different weight matrices, multiplying these weight matrices with hₙ to obtain the Q, K, V matrices;
(2.2) splitting the obtained Q, K, V matrices according to the number of designed multi-head self-attention heads, and then calculating the attention scores of the three parts respectively;

$${h}_{i}^{head} = Attention ( {QW}_{i}^{Q} , {KW}_{i}^{K} , {VW}_{i}^{V} )$$

wherein hᵢ^{head} represents the output of the i-th head, Wᵢ^{Q}, Wᵢ^{K} and Wᵢ^{V} are the parameter matrices of Q, K and V in the i-th head respectively;
(2.3) merging the calculation results:
wherein r is the number of heads of multi-head attention, W^{O} is the weight matrix when the multi-head self-attention mechanism merges the calculation results;
(2.4) obtaining the output feature v by merging and splicing the final multi-head self-attention calculation results and passing them through the linear layer;
(3) inputting the output feature v of the previous step into the convolutional capsule layer;
(3.1) between two adjacent capsules in the convolution capsule layer, multiplying the subcapsule vᵢ of the i-th layer by a weight matrix Wᵢ^{j} to obtain the prediction vector û_{j|i} from the subcapsule vᵢ to the parent capsule of the i+1-th layer:

$${\hat{u}}_{j \vert i} = {W}_{ij} {v}_{i}$$

(3.2) calculating the coupling coefficient cᵢⱼ determined by the dynamic routing algorithm, setting the initial value of the logarithmic probability bᵢⱼ to 0, and through the continuous transformation of cᵢⱼ, and conducting iterative update by using the softmax function:

$${c}_{ij} = \frac{exp ( {b}_{ij} )}{{\sum }_{j} exp ( {b}_{ij} )}$$

(3.3) obtaining the final feature representation sⱼ of each parent capsule by the weight sum of all the prediction vectors û_{j|i} from the child capsules:

$${s}_{j} = {\sum }_{j} {c}_{ij} {\hat{u}}_{j \vert i}$$

(3.4) the parent capsule sⱼ conducts scaling by using the activation function Squash, and then obtaining the final parent capsule Vⱼ:

$${V}_{j} = \frac{{‖ {s}_{j} ‖}^{2}}{1 + {‖ {s}_{j} ‖}^{2}} \cdot \frac{{s}_{j}}{‖ {s}_{j} ‖}$$

(3.5) inputting the output vector Vⱼ of the convolutional capsule layer into the classification capsule for classification:

$${V}_{f} = f ( W \cdot {V}_{j} + B )$$

wherein W represents the weight matrix of the classification capsule, and B represents the bias term of the classification capsule;
(3.6) inputting the vector V_{f} obtained after the classification of the classification capsule into the softmax classifier for normalization, then completing the detection and classification of unreliable information;
(3.7) wherein selecting the cross entropy function as the training loss function of the model, minimizing the cross entropy between the training predicted value and the actual value is the goal:

$$L = - \frac{1}{n} {\sum }_{x} [ y ln \hat{y} + ( 1 - y ) ln ( 1 - \hat{y} ) ]$$

wherein y and ŷ are the actual value and predicted value of sample x respectively, n is the number of training samples, and L is the loss value;
the method of inputting the word vector sequence x into the base model Transformer is:

$$y = softmax ( {W}_{Trans} \cdot Transformer\_Encoder ( x ) )$$

wherein Transformer_Encoder (x) represents the output of the word vector sequence x of the input text after applying the Transformer encoder; W_{Trans} represents the weight matrix of output layer in the base model Transformer; the softmax ( ) function converts the model output into a probability distribution to select the category of unreliable information;
the method of inputting the word vector sequence x into the base model BiTCN model is:

$$y = softmax ( {W}_{BiTCH} \cdot BiTCN ( x ) )$$

wherein BiTCN (x) represents the output obtained by applying BiTCN to the word vector sequence x of the input text; W_{BiTCH} represents the weight matrix of output layer in the base model BiTCN; the softmax ( ) function converts the model output into a probability distribution to select the category of unreliable information;
Step 3: conducting training and prediction on the three base models according to the 5-fold cross-validation step, and obtaining three sets of new training data and test data, splicing the three sets of new test data as a new test, the specific method is:
(1) firstly, dividing the data of training set into five parts, conducting training by using four parts of data of training set as the training set each time, and performing prediction by using a part of data of the remaining training set as the test set.
(2) after completing the model training, predicting the data of test set to obtain the prediction results;
(3) after repeating 5 times, that is, training the model for 5 times, splicing the 5 prediction results obtained on the training set to obtain a new set of features and training data, and arithmetically averaging the 5 prediction results on the test set to obtain a new set of test data.
(4) training the three base models through the above steps to obtain three sets of new training data and test data, splicing the three sets of new test data as a new test set.
Step 4: giving each of the three base models a credibility, that is, a weight, weighting the three sets of new training data and merging them as a new training set to input into the meta-learner SVM, the specific steps are:
(1) calculating the error rate of the t-th base model:

$${ϵ}_{t} = P ( {f}_{t} ( {\hat{y}}_{i} \neq {y}_{i} ) )$$

(2) calculating the weight αₜ according to the error rate:

$${α}_{t} = \frac{1 - {ϵ}_{t}}{{ϵ}_{t}}$$

(3) obtaining the final weight wₜ by normalizing the weight αₜ:

$${w}_{t} = \frac{{α}_{t}}{{\sum }_{i = 1}^{3} {α}_{t}}$$

(4) weighting three sets of new training data and merging them as a new training set to input into meta-learner SVM;
Step 5: training the new training data set by the meta-learner SVM, and obtaining the final classification result:

$$f ( x ) = sign ( w \cdot x + b )$$

wherein w is the weight matrix of the meta-learner SVM, and b is the bias term of the meta-learner SVM.

In order to verify the effectiveness of the invention, the following comparative experiment, ablation experiment and further comparative experiment of early detection capability are carried out:

in the selection of data set, the invention uses a classic data set Ma-Weibo for unreliable information detection tasks, the basic information of the data set is shown in the following table. The Ma-Weibo data set comprises a large number of blog posts collected from Sina Weibo Community Management Center, the language used in the blog posts is Chinese. The data set contains the original blog posts and the corresponding forwarding comments, which are suitable for the experiment of the invention. Based on the original data set, the experiment sorts and divides the forwarding comments corresponding to the blog posts according to the release time, which is conducive to the selection of early comments.

Basic information of data sets.

| Statistics | Ma-Weibo |
|---|---|
| Event samples | 4664 |
| Unreliable information | 2312 |
| Non-unreliable information | 2351 |
| Total number of comments | 3805656 |
| Average number of comments | 815.9 |

### (1) Comparative Experiment.

First of all, it can be determined that the number of forwarding comments on the blog post on the network platform is positively correlated with the release time of the blog post. For the same event, the longer the release time is, the more relevant forwarding comments will accumulate. Therefore, for the same event, the number of forwarding comments can be used to reflect the release time to a certain extent, so as to evaluate the early unreliable information detection performance of the model. Therefore, the comparative experiment selects the number of forwarding comments as the time cut-off line, and sets the cut-off line to 150, that is, only the first 150 forwarding comments of the corresponding event sorted by time are used for the experiment. By increasing the number of forwarding comments, the performance comparison of the seven comparative methods and the method proposed by the invention under different number of comments is evaluated, so as to detect the effect of this method when the number of early forwarding comments is small. The experiment selects seven unreliable information detection models for comparative experiments:

(1) SVM-TS: a time series model based on support vector machine (SVM), and it manually extracts 19 features related to unreliable information, and uses time series modeling techniques to fuse these features, which achieves the best result in unreliable information detection methods based on machine learning.

(2) GRU-2: it was proposed by Ma et al. when the deep neural network is applied to unreliable information detection tasks for the first time, at the same time, the Chinese data set Ma-Weibo used in this embodiment is also proposed, which is widely used and compared in the future. The model takes the event as a unit, uses two-layer GRU to learn the context information of event post, captures the changing characteristics of related posts over time, and achieves significant results in the task.

(3) PLAN: the PLAN model was proposed in the paper of the 2020 AAAI conference, and a Post-level attention model is proposed, at the same time, the multi-head self-attention mechanism in the Transformer network is used to modeling the long-distance dependence between tweets.

(4) HSA-BiLSTM: this model was proposed in the paper of the 27th CIKM conference, firstly, it establishes a hierarchical bidirectional long-term and short-term memory model to represent learning. Then, the attention mechanism is used to integrate social context information into the network, so as to introduce important semantic information into the model to improve the effect of unreliable information detection task. The HAS-BiLSTM model has achieved excellent results in the experiments of Chinese and English data sets.

(5) ARC: the model was proposed in the paper of the 28th CIKM conference, it is an attention residual network model combined with CNN, the model performs unreliable information detection based on content features. Firstly, the residual network with fine-tuning attention mechanism is used to capture long-distance dependence. Then, convolutional neural networks with different window sizes are used to select important components and local features, which achieves better result than other baseline models in the unreliable information detection task.

(6) DAPT: the model was proposed in the paper of the 12th CCWC in 2022, the DAPT model uses text analysis technology and pre-training method to improve the effect of early unreliable information detection, and uses data enhancement technology to alleviate the impact of the scarcity of unreliable information data to improve the performance of the model.

(7) BCMM-GRU: an enhanced representation method BCMM based on post is proposed, which can process the content of unreliable information event in the early stage of propagation, BCMM is combined with three-layer GRU to represent the content of post, the topological network of post and the metadata extracted from the post data set, so as to detect the unreliable information of post.

The comparative experimental results are shown in Table 4.1.

| Model | Data set | Acc | Prec | Rec | F1 |
|---|---|---|---|---|---|
| SVM-TS | Ma-Weibo | 0.832 | 0.838 | 0.830 | 0.834 |
| GRU-2 | Ma-Weibo | 0.847 | 0.843 | 0.856 | 0.849 |
| HSA-BiLSTM | Ma-Weibo | 0.853 | 0.847 | 0.861 | 0.854 |
| PLAN | Ma-Weibo | 0.860 | 0.864 | 0.856 | 0.860 |
| ARC | Ma-Weibo | 0.878 | 0.890 | 0.873 | 0.881 |
| DAPT | Ma-Weibo | 0.907 | 0.912 | 0.905 | 0.908 |
| BCMM-GRU | Ma-Weibo | 0.916 | 0.913 | 0.921 | 0.917 |
| Fusion model | Ma-Weibo | 0.931 | 0.926 | 0.942 | 0.940 |

When the number of forwarding comments is less than 150, it can be understood as the early stage of event release. At this time, unreliable information usually has not yet caused a greater impact, if it can be detected in time before the unreliable information forms an effective scale, then its subsequent impact can be reduced. According to the experimental results in the above table, it can be seen that the early detection method for network unreliable information based on ensemble learning proposed by the invention is superior to each comparison model in the four indicators of accuracy Acc, precision Prec, recall Rec and F1 value.

### (2) Ablation Experiment.

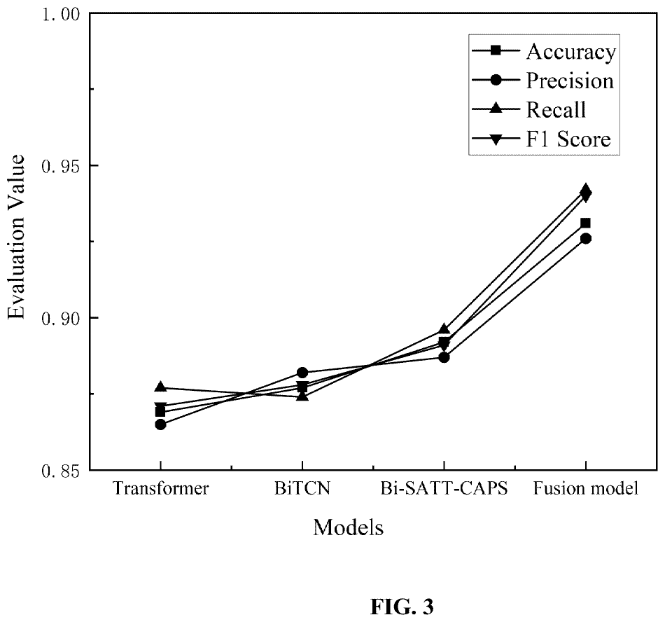

In order to verify the improvement of the multi-model fusion method on the experimental effect, the embodiment also carries out the corresponding ablation experiment on the data set Ma-weibo. The results of ablation experiments are shown in FIG. 3.

It can be seen from FIG. 3 that when the number of forwarding comments is 150, Bi-SATT-CAPS has achieved the best results compared with the other two base models, the four indicators have achieved the best results, the F1 value of Bi-SATT-CAPS is 0.013 higher than that of BiGCN model and 0.02 higher than that of Transformer model, which further proves the effectiveness of the invention. Compared with the three base models, the four indicators of the fusion model method have been greatly improved, the accuracy rate has increased by 3.9% compared with the highest Bi-SATT-CAPS in the base model, the precision rate has increased by 3.9%, the recall rate has increased by 4.6%, and the F1 value has increased by 0.049, which proves that the ensemble learning method can integrate the advantages and disadvantages of different models and obtain better performance than a single model.

### (3) Further Comparative Experiment of Early Detection Ability.

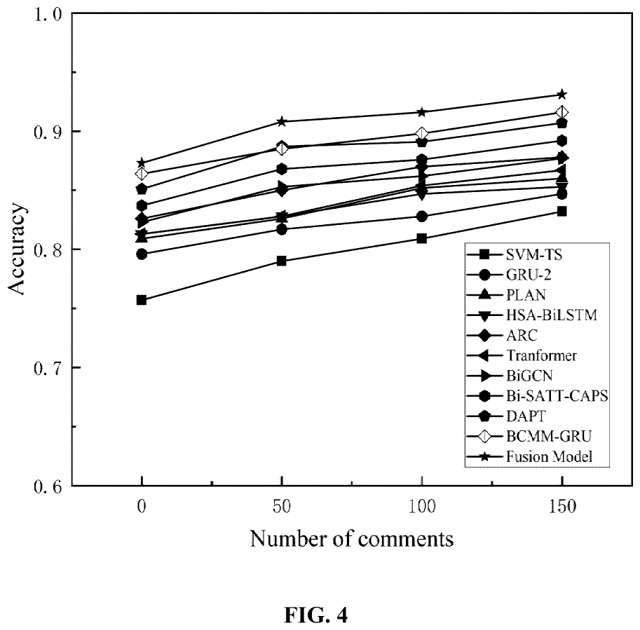

When the time cut-off line is set to 150, the experiment is subdivided again to verify the effect of various methods in the case of using 0-150 forwarding comments, the experimental results are shown in FIG. 4.

According to FIG. 4, it can be seen that as the number of comments increases, the accuracy of all models will increase. When the number of forwarding comments is less than 150, it can be understood as the early stage of event release. At this time, unreliable information usually has not yet caused a greater impact, if it can be detected in time before the unreliable information forms an effective scale, then its subsequent impact can be reduced. According to the experimental results, it can be seen that the detection accuracy of the fusion model method proposed by the invention is significantly better than that of each comparison model when the number of forwarding comments is less than 150. Specifically, when the number of comments is 50, the accuracy of the fusion model method is 2.3% higher than that of the BCMM-GRU model and 2.1% higher than that of the DAPT model. When the number of comments is 150, the accuracy of the fusion model method is 1.5% higher than that of the BCMM-GRU model and 2.4% higher than the DAPT model. From another perspective, in order to make the accuracy of the model reach 90%, the fusion model only needs less than 50 forwarding comments, while other models need to reach at least 150 forwarding comments. Therefore, it effectively verifies the effectiveness of the early unreliable information detection method proposed by the invention when the number of forwarding comments in the early stage of unreliable information release is small.

Therefore, the invention adopts the above-mentioned early detection method for network unreliable information based on ensemble learning, it introduces the capsule network into the unreliable information detection task, and uses the relationship between part and whole in the capsule network coding text to fully retain the grammatical and structural feature information of the text. The model fully considers the characteristics of network unreliable information data and effectively improves the effect of network unreliable information detection. By using the improved Stacking fusion strategy, the model Bi-SATT-CAPS, Transformer and BiTCN with different qualities proposed by the invention are fused to integrate the advantages and disadvantages of the three basic models, so as to improve the early detection performance of network unreliable information, only the blog post and a small amount of early forwarding comments can be used for high accuracy detection.

The above is the specific implementation method of the invention, but the protection scope of the invention should not be limited to this. Any change or replacement that can be easily imagined by technical personnel familiar in this field within the technical scope disclosed by the invention should be covered by the protection scope of the invention, so the protection scope of the invention should be limited by the claim.

What is claimed is:

1. An early detection method for network unreliable information based on ensemble learning comprises following steps:
Step 1: converting an input text sequence into a word vector sequence: firstly integrating a corresponding forwarding comment c in an original blog post s to obtain a text sequence M=[m₁, m₂, . . . , mₙ] with a length of n, then using a pre-trained Glove to convert the text sequence M into a word vector sequence x, x=x₁, x₂, . . . , xₙ (xᵢ∈Rd), wherein d represents dimension;
Step 2: inputting the word vector sequence into three base models Transformer, Bi-SATT-CAPS, and BiTCN to complete a classification of unreliable information detection, using the base model Bi-SATT-CAPS to obtain classification method steps of unreliable information detection:
(1) inputting the word vector sequence x into a bidirectional LSTM for feature extraction, obtaining the vector by splicing hidden state vectors of a forward LSTM and a reverse LSTM to represent extracted features:
$${h}_{n} = [ \overline{{h}_{n}} , \overline{{h}_{n}} ]$$
wherein h̅ₙ̅ represents the hidden state vector of the forward LSTM, h̅ₙ̅ represents the hidden state vector of the reverse LSTM, [,] represents the splicing operation;
(2) using a multi-head self-attention mechanism to perform a multi-head self-attention calculation on an output hₙ of the bidirectional LSTM, achieving common attention to input information at different positions;
(2.1) W_{Q}, Wₖ, Wᵥ are different weight matrices, multiplying these weight matrices with hₙ to obtain Q, K, V matrices;
(2.2) splitting the obtained Q, K, V matrices according to a number of designed multi-head self-attention heads, and then calculating attention scores of three parts respectively;
$${h}_{i}^{head} = Attention ( {QW}_{i}^{Q} , {KW}_{i}^{K} , {VW}_{i}^{V} )$$
wherein hᵢ^{head} represents the output of an i-th head, Wi_{Q}, Wi_{K} and Wi_{V} are the parameter matrices of Q, K and V in the i-th head respectively;
(2.3) merging calculation results:
wherein r is the number of heads of multi-head self-attention, W^{O} is the weight matrix when the multi-head self-attention mechanism merges the calculation results;
(2.4) obtaining an output feature v by merging and splicing final multi-head self-attention calculation results and passing them through a linear layer;
(3) inputting the output feature v of a previous step into an convolutional capsule layer;
(3.1) Between two adjacent capsules in the convolution capsule layer, multiplying a subcapsule vᵢ of an i-th layer by a weight matrix Wᵢⱼ to obtain a prediction vector û_{j|i} from the subcapsule vᵢ to a parent capsule of a i+1-th layer:
$${\hat{u}}_{j \vert i} = {W}_{ij} {v}_{i}$$
(3.2) Calculating a coupling coefficient cᵢⱼ determined by a dynamic routing algorithm, setting an initial value of a logarithmic probability bᵢⱼ to 0, and through continuous transformation of cᵢⱼ, conducting an iterative update by using a softmax function:
$${c}_{ij} = \frac{exp ( {b}_{ij} )}{{\sum }_{j} exp ( {b}_{ij} )}$$
(3.3) Obtaining a final feature representation sⱼ of each parent capsule by a weight sum of all prediction vectors û_{j|i} from child capsules.
$${s}_{j} = {\sum }_{i} {c}_{ij} {\hat{u}}_{ji}$$
(3.4) the parent capsule sⱼ conducts scaling by using an activation function Squash, and then obtaining a final parent capsule Vⱼ:
$${V}_{i} = \frac{{‖ {s}_{j} ‖}^{2}}{1 + {‖ {s}_{j} ‖}^{2}} \cdot \frac{{s}_{i}}{‖ {s}_{j} ‖}$$
(3.5) inputting the output vector Vⱼ of the convolutional capsule layer into the classification capsule for classification:
$${V}_{f} = f ( W \cdot {V}_{j} + B )$$
wherein W represents the weight matrix of the classification capsule, and B represents a bias term of the classification capsule;
(3.6) inputting a vector V_{f} obtained after the classification of a classification capsule into a softmax classifier for normalization, then completing detection and classification of unreliable information;
(3.7) wherein selecting a cross entropy function as a training loss function of the model, minimizing the cross entropy between a training predicted value and an actual value is goal:
$$L = - \frac{1}{n} {\sum }_{x} [ y ln y + ( 1 - y ) ln ( 1 - \hat{y} ) ]$$
wherein y and ŷ are the actual value and predicted value of a sample x respectively, n is the number of training samples, and Lis a loss value;
Step 3: conducting training and prediction on the three base models according to a 5-fold cross-validation step, and obtaining three sets of new training data and test data, splicing the three sets of new test data as a new test set;
Step 4: giving each of the three base models a credibility, that is, a weight, weighting the three sets of new training data and merging them as a new training set to input into a meta-learner SVM, the specific steps are:
(1) calculating an error rate of a t-th base model:
$${ϵ}_{i} = P ( f , ( {\hat{y}}_{i} \neq {y}_{i} ) )$$
(2) calculating a weight at according to the error rate:
$${α}_{t} = \frac{1 - {ϵ}_{i}}{{ϵ}_{i}}$$
(3) obtaining a final weight wₜ by normalizing the weight αt:
$${w}_{t} = \frac{{α}_{i}}{{\sum }_{i = 1}^{3} {α}_{i}}$$
(4) weighting three sets of new training data and merging them as the new training set to input into the meta-learner SVM;
Step 5: training the new training set by the meta-learner SVM, and obtaining the final classification result:
$$f ( x ) = sign ( w \cdot x + b )$$
wherein w is the weight matrix of the meta-learner SVM, and b is the bias term of the meta-learner SVM.

2. The early detection method for network unreliable information based on ensemble learning according to claim 1, in S2, the method of inputting the word vector sequence x into the base model Transformer is:
$$y = softmax ( {W}_{trans} \cdot Transformer\_Encoder ( x ) )$$
wherein Transformer_Encoder (x) represents the output of the word vector sequence x of the input text after applying a Transformer encoder; W_{Trans} represents the weight matrix of output layer in the base model Transformer; the softmax ( ) function converts the model output into a probability distribution to select a category of unreliable information;
the method of inputting the word vector sequence x into the base model BiTCN model is:
$$y = softmax ( {W}_{BiTCH} \cdot BiTCN ( x ) )$$
wherein BiTCN (x) represents the output obtained by applying BiTCN to the word vector sequence x of the input text; W_{BiTCH} represents the weight matrix of output layer in the base model BiTCN; the softmax ( ) function converts the model output into a probability distribution to select the category of unreliable information.

3. The early detection method for network unreliable information based on ensemble learning according to claim 1, the specific method of step 3 is:
(1) firstly, dividing the data of training set into five parts, conducting training by using four parts of the data of training set as the training set each time, and performing prediction by using a part of data of remaining training set as the test set;
(2) after completing the model training, predicting the data of test set to obtain prediction results;
(3) after repeating 5 times, that is, training the model for 5 times, splicing the 5 prediction results obtained on the training set to obtain the new set of features and training data, and arithmetically averaging the 5 prediction results on the test set to obtain a new set of test data;
(4) training the three base models through the above steps to obtain three sets of new training data and test data, splicing the three sets of new test data as the new test set.
